(19) United States
(12) Patent Application Publication
(10) Pub. No.: US 2019/0338410 A1
(43) Pub. Date: Nov. 7, 2019

(54) ALTERNATING TANGENT MOUNTED EVAPORATIVE DEPOSITION SOURCE MECHANISM FOR RAPID CYCLE COATING

(71) Applicant: Vergason Technology, Inc., Van Etten, NY (US)

(72) Inventors: Richard Ruben, Spencer, NY (US); Gary Vergason, Athens, PA (US); Andrew Polzella, Athens, PA (US)

(73) Assignee: Vergason Technology, Inc., Van Etten, NY (US)

(21) Appl. No.: 16/401,761

(22) Filed: May 2, 2019

Related U.S. Application Data
(60) Provisional application No. 62/666,175, filed on May 3, 2018.

(51) Int. Cl. C23C 14/24; C23C 14/14

(52) U.S. Cl. CPC C23C 14/24; C23C 14/14

(57) ABSTRACT

An evaporation source mechanism for rapid cycle coating. The evaporation source mechanism has a housing with a first deposition area on a first side and a second deposition area on a second side. The housing is movably connected to vacuum chamber such that the housing is rotatable relative to the vacuum chamber so that one side is in the deposition coating process and the other side is simultaneously loaded/reloaded. While one deposition area is in process under vacuum, the other is being prepared for the next cycle. When the coating cycle is complete, the housing swings from a port on the vacuum chamber, is rotated, and is then positioned with the second side of the housing against a sealing surface on the vacuum chamber wall. The coating system is away and electrically isolated from the loading/reloading of sources, permitting safe and efficient use of the equipment.

### CROSS-REFERENCE TO RELATED APPLICATIONS

This application claims priority to U.S. Provisional Patent Application Ser. No. 62/666,175 filed on May 3, 2018 and entitled “Alternating Tangent Mounted Evaporative Deposition Source Mechanism for Rapid Cycle Coating,” the entirety of which is incorporated herein by reference.

### BACKGROUND OF THE INVENTION

### 1. Field of the Invention

The present invention is directed generally to an evaporation source mechanism and, more particularly, to an alternating tangent mounted evaporative deposition source mechanism for rapid-cycle coating.

### 2. Description of Related Art

Thermal evaporation is the vaporization of a material by heating to a temperature such that the vapor pressure becomes appreciable and atoms or molecules are lost from the hot surface in a vacuum. A coating or film is formed when these atoms or molecules condense on a surface. The possibility of depositing thin metal films in a vacuum by heating of a supporting wire was reported by Narhwold in 1887 (Nahrwold, R., Ann. Physik, 34, 473 (1887)), where he used a platinum wire. Thermal evaporation by heating to incandescence and film deposition was covered by Edison's 1894 patent. Edison, T. A., “The Art of Plating One Material on Another,” U.S. Pat. No. 526,147, (1894).

In 1912, von Pohl and Pringsheim reported forming films by evaporating material in a vacuum from a magnesia crucible that was heated by a resistively heated foil surrounding the crucible. R. von Pohl and P. Pringsheim, “Über die Herstellung von Metallspiegeln durch Distillation im Vakuum,” Verhandl. Deut. Physik. Ges., 14, 506 (1912). In 1931, Ritschl reported thermal evaporation of silver from a tungsten wire basket to form half-silvered mirrors. R. Ritschl, Zeits. F. Physik, 69, 578 (1931). Ritschl is often credited with being the first to use evaporation from a filament to form a film in vacuum. In 1931, the US National Bureau of Standards stated, “This method of deposition [thermal evaporation] has not been widely tested, and its possibilities are therefore little known, but it would seem to be especially valuable for small work where films of any readily volatile substance were required.” I. C. Gardner and F. A. Case, “The Making of Mirrors by the Deposition of Metals on Glass,” Bureau of Standards, Circular #389 (January 1931).

Strong, with the help of designer Bruce Rule, aluminum coated the 200″ Palomar (“Hale”) astronomical telescope mirror in 1947 using multiple (350) filaments and a 19 foot diameter vacuum chamber. J. A. F. Trueman, “The Design and Operation of Large Telescope Mirror Aluminizers,” p. 32 in Proceedings of the 22nd Annual Technical Conference, Society of Vacuum Coaters (1979). In 1937, D. Wright of GE began development of the sealed-beam headlight, which first appeared on autos in 1940. F. Adams “Vacuum Metallizing in the Lamp Industry,” p. 48 in Proceedings of the 23rd Annual Technical Conference, Society of Vacuum Coaters (1980).

A wide range of materials are commonly evaporated. Some materials vaporize sufficiently under vacuum at temperatures that are solid—they are said to sublime. Examples are Cr and Mg. Other materials do not vaporize sufficiently unless molten—these are said to evaporate. Examples are Al, Sn, Mo and W. Both processes are categorized as “thermal evaporation” in this context. Single species metals are commonly evaporated. Many compound films can be grown by evaporating compound sources, while other compound films are formed by simultaneously evaporating from separate sources, by simultaneously flowing reactive gases, or both. In 1952, Aüwarter patented the evaporation of metals in a reactive gas to form films of compound materials, (M. Ailwarter, Austrian Patent #192,650 (1952)), followed shortly by Brinsmaid in the US. D. S. Brinsmaid, G. J. Koch, W. J. Keenan, and W. F. Parson, U.S. Pat. No. 2,784,115 (1957).

There are requirements for successful evaporative coatings. Glang concisely describes the requirements for thin-film evaporation sources. R. Glang, “Vacuum Evaporation,” pg. 1-36, Chap. 1 in Handbook of Thin Film Technology, L. I. Maissel and R. Glang, eds., McGraw-Hill (1970). “The evaporation of materials in a vacuum system requires a vapor source to support the evaporant and to supply the heat of vaporization while maintaining the charge at a temperature sufficiently high to produce the desired vapor pressure . . . Rough estimates of source operating temperatures are commonly based on the assumption that vapor pressures of 10E-2 Torr must be established to produce useful film condensation rates. For most materials of practical interest, these temperatures fall into the range from 1000 to 2000° C.” In order to produce highly reflective aluminum films, the vacuum level in the process chamber must be low enough to remove contaminant species. In many processes, this requires a base pressure of 10E-5 Torr.

Several configurations have been developed for placing the source material into the vacuum chamber and applying heat to drive the evaporation process. Several of these incorporate a container of some sort, often referred to as a crucible. Others apply the source material to a filament of some material, as first described by Edison. Examples are shown in FIGS. 15-19. Common methods of applying heat are electrical resistance, focused electron beam, and induction. A wide variety of containers are available for heat delivered by electrical current driven through the resistance of the container (see RD Mathis, others). Depending on the apertures, the flux of material can be directed. One example of directed deposition is Hibi, who positioned a tube between the source and the substrate. T. Hibi, Review of Scientific Instrumentation vol 23, p 383 (1952). A common method to deliver heat is to use a focused beam of highly accelerated electrons, first reported by O'Bryan in 1934. H. M. O'Bryan, “Evaporation technique for highly refractive substances,” Rev. Sci. Instrum. 5, 125 (1934). Another is to wrap a crucible with electrically conductive, water cooled coils and impose a high frequency electric current. This induces an electric current in the crucible contents, and is termed inductive heating. Lasers have been used to flash evaporate small quantities of evaporant. H. M. Smith and A. F. Turner, “Vacuum Deposited Thin Films Using a Ruby Laser,” Appl. Optics, 4, 147 (1965).

Maximizing the profitability of coating operations requires maximizing the product of rate of parts produced (throughput), time depositing (uptime), deposition rate, and yield. Traditional evaporation systems were batch systems with a single access port, which followed the sequence shown in FIG. 1. In order to minimize the time the system was not actually depositing, a variety of methods have been developed to prevent venting the system for introducing parts or for reloading evaporation sources. These are covered in CPC classes C23C 14/56 and C23C 14/246 respectively. Class C23C 14/56 describes systems referred to as “inline” or “load locked” systems. All of the source replenishment methods identified in CPC class C23C 14/246 are methods to replenish the source while the source is under vacuum. In order to increase throughput, systems are made as large as practical to accommodate as many parts at one time a possible. However, there remain applications where the capital expense for these approaches is not warranted, and batch systems are employed.

The batch approach outlined schematically in FIG. 1 is cyclically repeated. As soon as the system is vented, finished parts are removed. Then, the sources are replenished. If they are the sort that is fully expended with each cycle, they are replaced. If they are the sort that can be refilled, they are refilled. This is done before fresh substrates are loaded to minimize the possibility of particulate contamination of the part surfaces. Once the parts are loaded, the system is closed and sealed. The system is then evacuated to the required base pressure. If that pressure cannot be attained, the most recently opened seals are opened, cleaned, and checked before being once more closed and sealed. Once the required base pressure is attained, the coating process is started.

The need to maximize throughput of batch systems remains. Large systems can utilize multiple sources to coat as many parts as possible in each cycle. Systems with cartridges or magazines of parts and of sources are known. These allow operators to minimize the handling while the system is in the vented state. They can load individual parts while the pumping and deposition processes are underway.

Twin door systems are known where one door holds parts that are being processed while the other door is being unloaded and reloaded. This is a significant advantage over cartridge arrangements because the permanently attached door provides reliable, positive registration to the rest of the system. It also provides an integral seal that is known to be reliable, based on the immediately previous utilization.

If the sources are also located on the doors, source replenishment can also occur during the exchange. However, the operations of exchanging substrates and sources, when performed on the same door, interfere with each other. With one person performing the substrate operations, a person cannot simultaneously exchange or refill sources.

Generally, the number of penetrations and O-ring sealed flanges is minimized in vacuum deposition system design. In most well-designed systems using elastomer O-ring seals, the seals are an important source of system gas load, and often determine the ultimate pressure. Addition of such sealed flanges must be done properly and with good cause. Construction of a vessel from a frame with multiple panels is known. However, such approaches do not address the need for doors or panels with precise alignment and hinging for rapid change. See, for example, FIG. 13 in Hauser U.S. Pat. No. 5,234,561 for a cathodic arc and sputtering system. Double doors are known in clean rooms, where one door opens into the clean room for exchange of parts and recharge of sources, while the other door opens for maintenance and cleaning operations into maintenance bay, but both are not opened simultaneously opened, so as to preserve clean room integrity.

Therefore, there is a need for a means to capture, for sources, the benefits of the twin door arrangement used for substrates, while eliminating the interference with the substrate exchange operation, minimizing the time between venting and pumping.

Description of the Related Art Section Disclaimer: To the extent that specific patents/publications/products are discussed above in this Description of the Related Art Section or elsewhere in this disclosure, these discussions should not be taken as an admission that the discussed patents/publications/products are prior art for patent law purposes. For example, some or all of the discussed patents/publications/products may not be sufficiently early in time, may not reflect subject matter developed early enough in time and/or may not be sufficiently enabling so as to amount to prior art for patent law purposes. To the extent that specific patents/publications/products are discussed above in this Description of the Related Art Section and/or throughout the application, the descriptions/disclosures of which are all hereby incorporated by reference into this document in their respective entirety(ies).

### SUMMARY OF THE INVENTION

Embodiments of the present invention are directed to a mechanism, system, and method for source replenishment in a batch manner, not a continuous manner or while the source in under vacuum.

According to an aspect, an embodiment of the present invention is directed to an evaporation source mechanism. The mechanism includes a housing having a first side and a second side. The housing is rotatable between a first evaporative configuration and a second evaporative configuration. The mechanism additionally has a first deposition area on the first side of the housing and a second deposition area on the second side of the housing. The first deposition area is configured to temporarily store a first set of one or more sources and the second deposition area is configured to store a second set of one or more sources. In the first evaporative configuration, the first deposition area is configured for energizing the first set and the second deposition area is configured for loading the second set into the second deposition area. In the second evaporative configuration, the second deposition area is configured for energizing the second set and the first deposition area is configured for loading the first set into the first deposition area.

According to another aspect, the present invention is directed to a coating system. The system includes a vacuum chamber having a sealing surface and an evaporation source mechanism. The evaporation source mechanism includes a housing having a first side and a second side. The evaporation source mechanism also includes a first deposition area on the first side of the housing and a second deposition area on the second side of the housing. The housing of the evaporative source mechanism is rotatable between a first evaporative configuration and a second evaporative configuration relative to the sealing surface of the vacuum chamber. In the first evaporative configuration, the first side of the housing is mated with the sealing surface of the vacuum chamber and in the second evaporative configuration, the second side of the housing is mated with the sealing surface of the vacuum chamber.

According to yet another aspect, the present invention is directed to a method for rapid cycle coating. The method includes the steps of: (i) providing an evaporation system including a vacuum chamber having a sealing surface with a port, and an evaporation source mechanism comprising a housing having a first side and a second side, a first deposition area on the first side of the housing having a first set of one or more sources loaded therein, and a second deposition area on the second side of the housing, wherein the evaporation source mechanism is movably attached to the vacuum chamber; (ii) sealing the first side of the housing to the sealing surface of vacuum chamber such that the port engages the first deposition area and the second side of the housing is exposed; (iii) loading a second set of one or more sources into the second deposition area on the second side of the housing while evaporating an evaporation material from the first set of one or more sources loaded in the first deposition area; (iv) rotating the housing and sealing the second side of the housing to the sealing surface of the vacuum chamber such that the port engages the second deposition area and the first side of the housing is exposed; and (v) evaporating an evaporation material from the second set of one or more sources loaded in the second deposition area via the port on the vacuum chamber while reloading the first set of one or more sources in the first deposition area on the exposed first side of the housing.

These and other aspects of the invention will be apparent from the embodiments described below.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following description taken in conjunction with the accompanying drawings in which:

FIG. 1 is a flowchart of a schematic sequence of operations of prior art methods of operating thin film vacuum coating systems;

FIG. 2 is a flowchart of a schematic sequence of operations of prior art methods of operating double-door thin film vacuum coating systems with sources that must be replenished inside the system each run;

FIG. 3 is a flowchart of a schematic sequence of operations of prior art methods of operating double-door thin film vacuum coating systems with sources that that must be replenished on the alternate door each run;

FIG. 4 is an isometric view schematic representation of an evaporation source mechanism, according to an embodiment;

FIG. 5 is a top view schematic representation of the evaporation source mechanism is the first evaporative configuration, according to an embodiment;

FIG. 6 is a top view schematic representation of the evaporation source mechanism is the first intermediate configuration, according to an embodiment;

FIG. 7 is a top view schematic representation of the evaporation source mechanism rotating, according to an embodiment;

FIG. 8 is a detail view schematic representation of the evaporation source mechanism of FIG. 7;

FIG. 9 is side perspective view schematic representation of the evaporation source mechanism in the first evaporative configuration, according to an embodiment;

FIG. 10 is side perspective view schematic representation of the evaporation source mechanism in the first intermediate configuration, according to an embodiment;

FIG. 11 is side perspective view schematic representation of the evaporation source mechanism rotating, according to an embodiment;

FIG. 12 is side perspective view schematic representation of the evaporation source mechanism in the second intermediate configuration, according to an embodiment;

FIG. 13 is side perspective view schematic representation of the evaporation source mechanism in the second evaporative configuration, according to an embodiment;

FIG. 14 is a flowchart of the operation sequence of the evaporation system, according to an embodiment;

FIG. 15 is a filament source;

FIG. 16 is a crucible in a filament basket;

FIG. 17 is a crucible source;

FIG. 18 is a boat source;

FIG. 19 is a box source;

FIG. 20 is diagram of the coating system, according to an embodiment; and

FIG. 21 is electrical schematic of an array of sources, according to an embodiment.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known structures are omitted so as not to unnecessarily obscure the invention in detail. It should be understood, however, that the detailed description and the specific non-limiting examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

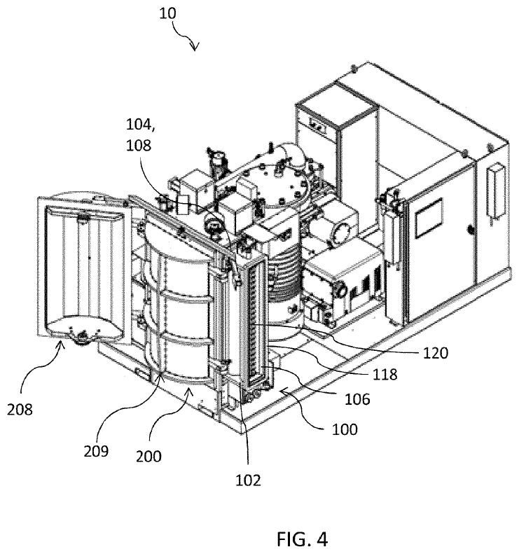

Referring now to the figures, wherein like reference numerals refer to like parts throughout, FIG. 4 shows an isometric view schematic representation of an evaporation source mechanism 100, according to an embodiment. In the depicted embodiment, the coating system 10 comprises a vacuum chamber 200 having a hinged, rotating evaporation source mechanism 100 attached thereto. The evaporation source mechanism 100 can be mounted to any stationary portion of the chamber 200 such that the evaporation source mechanism 100 is rotatable relative to the chamber 200. Although the evaporation source mechanism 100 is hingedly connected to the vacuum chamber 200 in FIG. 4, any other rotation mechanism or movable connection means can be used. For example, one or more pneumatic cylinders can extend from a rail or other feature of the vacuum chamber 200.

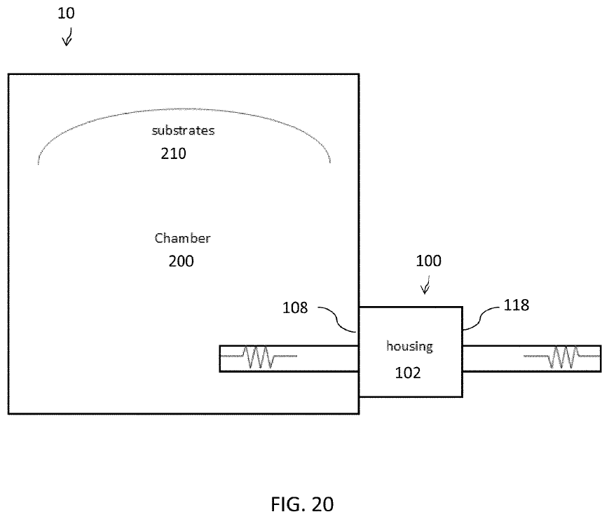

Still referring to FIG. 4, the vacuum chamber 200 of the system 10 comprises one or more doors 208, 209 to close and seal the vacuum chamber 200. As shown in FIG. 20, substrates 210 to be coated are placed within the chamber 200 (through the doors 208, 209 in FIG. 4), as done with conventional coating systems. In another embodiment, the substrates 210 to be coated are placed within the doors 208, 209, such as in holding structures in the doors 208, 209, for example. In an embodiment of the coating system 10, the chamber 200 is also vented to the atmosphere.

Referring back to FIG. 4, the evaporation source mechanism 100 comprises a rigid housing 102 (or enclosure) having a first side 108 with a first deposition area 104 and a second side 118 with a second deposition area 106. The first and second deposition areas 104, 106 are any type of recess, bank, concavity, or holder in the sides 108, 118 of the housing 102 configured to receive one or more sources 120 (which comprise “evaporation materials,” such as metals) for the coating process. For example, in FIG. 4, a plurality of sources 120 are shown in the second deposition area 106 on the second side 118 of the housing 102.

The evaporation source mechanism 100 is rotatable between a first evaporative configuration and a second evaporative configuration. In the first evaporative configuration, the chamber 200 can utilize the sources 120 in the first deposition area 104 and in the second evaporative configuration, the chamber 200 can utilize the sources 120 the second deposition area 106, as described below. Although the housing 102 has two sides 108, 118 with a total of two deposition areas 104, 106 in FIG. 4, the housing 102 can be configured to have additional sides (e.g., a triangular housing with three sides and a total of three deposition areas).

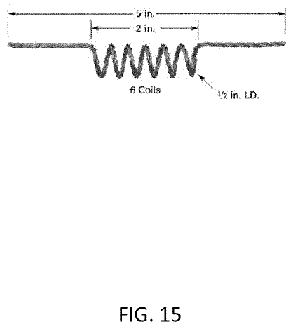

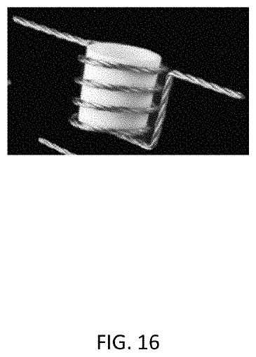

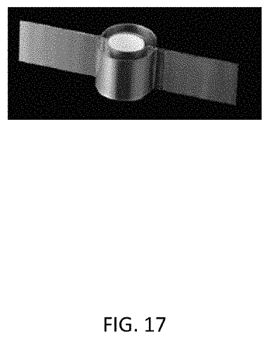

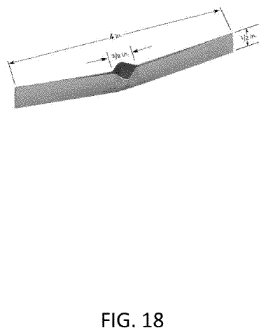

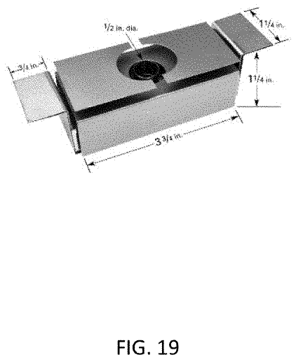

Any thermal evaporation source 120 can be configured for loading/reloading into the first and second deposition areas 104, 106, such as the commercially available evaporation sources shown in FIGS. 15-19 (e.g., a filament source, a crucible source, a crucible in a filament basket, a boat source, and a box source). The sources 120 included in the deposition areas 104, 106 can be composed of the same evaporation materials (e.g., copper); however, it is not required. Thus, the first deposition area 104 can be loaded/reloaded with the same type of sources 120 as those loaded/reloaded into second deposition area 106.

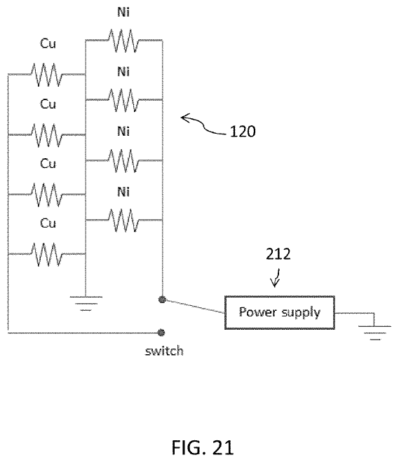

Similarly, each deposition area 104, 106 can be loaded/reloaded with two or more different sources 120. In fact, if a mix of conductors (e.g., connected in an array) is provided to a common return and a switch bank, different sets of sources 120 in one of the deposition areas 104, 106 could be powered at different times (not both deposition areas 104, 106 at once), such as that shown in FIG. 21, creating individual, sequential layers of thin films at once. In theory, there is no limit on the number of such circuits for a particular deposition area 104, 106. In the example shown in FIG. 21, the sources 120 include copper (Cu) and nickel (Ni), which can be used in the coating process to create a layer of nickel and subsequently, a layer of copper thereon. This multi-layer coating occurs without venting, which increases the efficiency of the evaporation source mechanism 100.

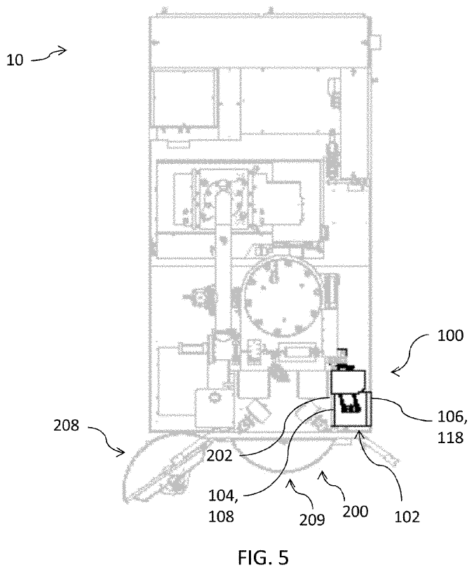

Turning now to FIGS. 5-7, there are shown top views schematic representations of the evaporation source mechanism 100 rotating from the first evaporative configuration. In the first evaporative configuration, shown in FIG. 5, the first side 108 of the housing 102 mates with a sealing surface 202 of the chamber 200. In particular, the first side 108 of the housing 102 mates flush against the sealing surface 202 of the chamber 200. The first side 108 of the housing 102 comprises a seal (not shown) for mating with the chamber 200 to create a vacuum seal. Although the first side 108 of the housing 102 mates flush with the sealing surface 202 of the chamber 200, portions or components of the housing 102 may extend into the chamber 200. As recited above, the first side 108 of the housing 102 comprises the first deposition area 104. Thus, if the first deposition area 104 had been previously loaded with one or more sources 120, the chamber 200 can utilize the source(s) 120 in the first deposition area 104 when the evaporation source mechanism 100 is in the first evaporative configuration.

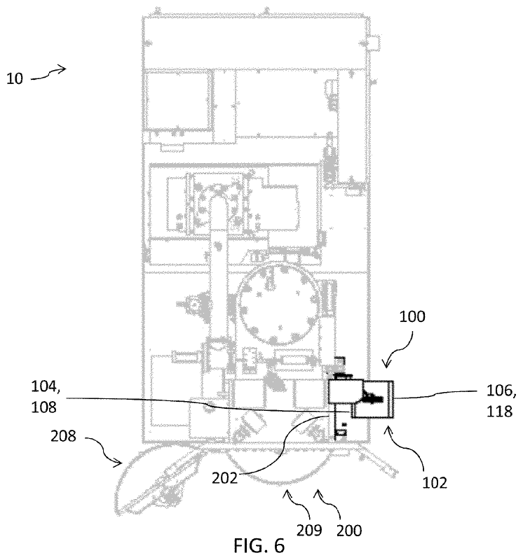

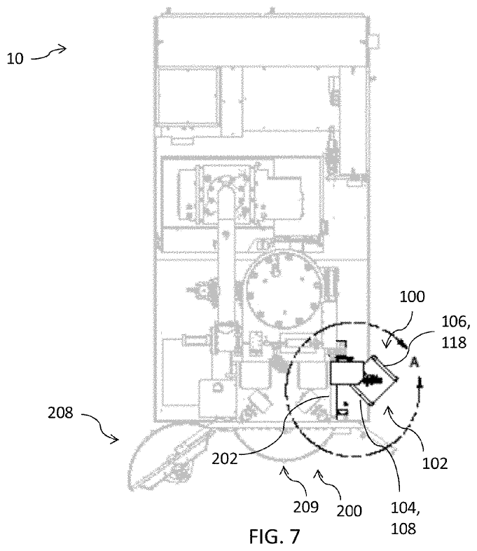

The housing 102 is rotatable about the chamber 200 to a retracted position, shown in FIG. 6, wherein the housing 102 is open from the chamber 200. In other words, the vacuum seal connection between the first side 108 of the housing 102 and the chamber 200 is broken in the retracted position. Once the housing 102 of the evaporation source mechanism 100 is open in the retracted position, the housing 102 is rotatable or otherwise pivotable clockwise or counterclockwise, as shown in FIG. 7.

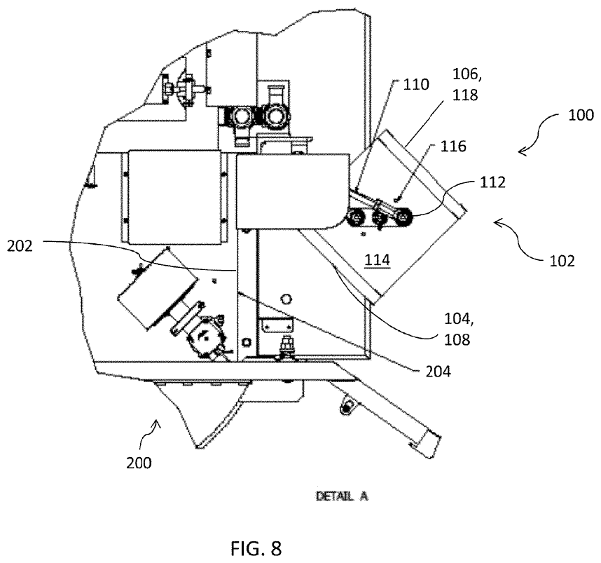

Turning now to FIG. 8, there is shown a detail view schematic representation of the evaporation source mechanism 100 of FIG. 7. In the depicted embodiment, the housing 102 of the evaporation source mechanism 100 is connected to the chamber 200 via a pair of swing arms 110. The swing arms 110 provide a hinged connection between the housing 102 and the chamber 200. The swing arms 110 are attached to the chamber 200 and to rotational bearings 112 on a surface 114 of the housing 102, as shown in FIG. 8. The swing arms 110 allow the housing 102 to move from the first configuration, closed and sealed to the sealing surface 202 of the chamber 200, to the retracted position, away from the sealing surface 202 of the chamber 200.

Still referring to FIG. 8, with the housing 102 moved away from the sealing surface 202 of the chamber 200, the housing 102 is rotatable about the rotational bearings 112 so that the first side 108 of the housing 102 is at an angle relative to the sealing surface 202 of the chamber 200. As also shown in FIG. 8, the surface 114 of the housing 102 may also comprise a plurality of spring-loaded detents 116 for proper rotational positioning. Although not shown in FIG. 8, the base (not shown) of the housing 102 is supported on an arm (similar to the swing arms 110) containing bearings (like the rotational bearings 112) that permit the swinging motion and the rotational motion of the housing 102. The swing arms 110 and similarly, the arm on the base of housing 102, are mounted securely to the chamber 200 and contain travel limits to prevent over extension thereof.

Although not shown in FIG. 8, the housing 102 may also have a clamping mechanism that will retain the housing 102 at the sealing surface 202 of the chamber 200 in the first evaporative configuration. As shown in FIG. 8, with the evaporation source mechanism 100 in the first intermediate configuration, a port 204 (for the first and second deposition areas 104, 106) on the sealing surface 202 of the chamber 200 is exposed. The electrical connection to a power supply (e.g., power supply 212 of FIG. 21) of the evaporation system 10 is made when the housing 102 is clamped in position at the port 204 on the chamber 200. The electrical connection can only be made to the side (e.g., first side 108) of the housing 102 that is in use and completely and physically disconnected to the opposing side (e.g., second side 118), as shown in FIG. 20. Thus, electrical connection with the active first deposition area 104, for example, is positively engaged, while no means of electrical connection with inactive, second deposition area 106 is possible. Further, the housing 102 may also comprise a sensor (not shown) for its position in relation to the sealing surface 202 of the chamber 200.

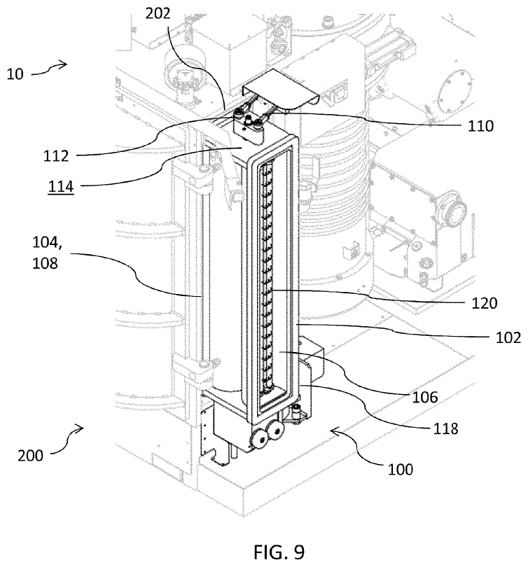

Turning now to FIGS. 9-13, there are shown side perspective views schematic representations of the evaporation source mechanism 100 moving or rotating 180 degrees between the first evaporative configuration and the second evaporative configuration, according to an embodiment. In conventional coating processes, one or more substrates 210 are first loaded into the vacuum chamber 200 (as shown generally in FIG. 20). Assuming the first deposition area 104 has been loaded with one or more sources 120, when the evaporation source mechanism 100 is in the first evaporative configuration with the first side 108 of the housing 102 vacuum sealed flush against the sealing surface 202 of the chamber 200, the coating process can begin. The source(s) 120 in the first deposition area 104 is energized.

Still referring to FIG. 9, in the first evaporative configuration, the swing arms 110 are substantially parallel, extending from the chamber 200 to the rotational bearings 112 on the surface 114 of the housing 102. As shown, the second side 118 of the housing 102 is exposed to the environment in the first evaporative configuration. The second side 118 of the housing 102 comprises the second deposition area 106; thus, the second deposition area 106 is exposed to the environment while the source(s) 120 in the first deposition area 104 is energized.

With the second deposition area 106 exposed, a user may load/reload the second deposition area 106 with one or more sources 120. As described above, a single source 120 can be used or different sources 120 (e.g., an array of varying sources 120) can be used. The loading/reloading of the second deposition area 106 can occur while the coating process occurs using the source(s) 120 in the first deposition area 104 on the first side 108 of the housing 102. Both the coating process and the loading/reloading process can occur simultaneously because the first side 108 of the housing 102 is electrically disconnected to the second side 118 of the housing 102.

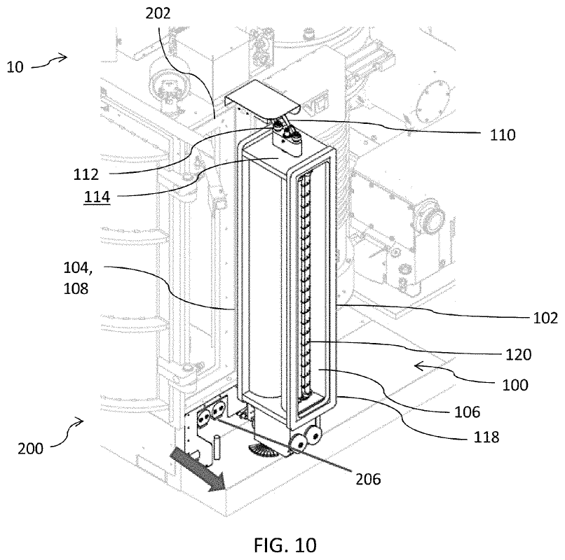

From the first evaporative configuration, the housing 102 rotates via the swing arms 110 to the retracted position, as shown in FIG. 10. In the retracted position, the housing 102 is open and spaced from the sealing surface 202 of the chamber 200. Thus, both the first deposition area 104 and the second deposition area 106 of the housing 102 are exposed. As also shown in FIG. 10, in the retracted position, electrical contacts 206 on the sealing surface 202 of the chamber 200 are exposed. Therefore, in the retracted position, the first side 108 of the housing 102 is electrically disconnected from the chamber 200.

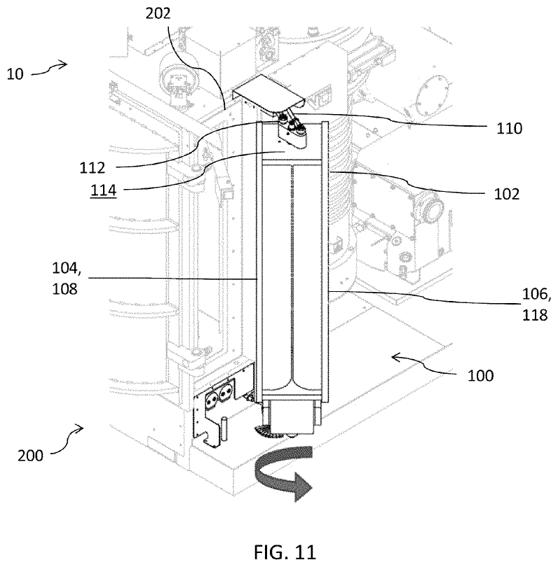

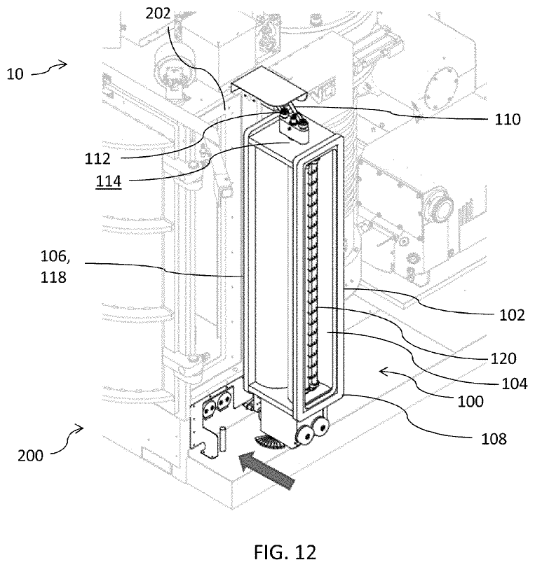

Turning now to FIG. 11, there is shown the housing 102 rotating from the retracted position toward the second evaporative configuration. From the retracted position, the housing 102 rotates or pivots about the rotational bearings 112 such that the first side 108 of the housing 102 (having the first deposition area 104) extends at an angle relative to the sealing surface 202 of the chamber 200. The housing 102 is continuously rotated or pivoted about the rotational bearings 112 to a rotated, retracted position, in FIG. 12.

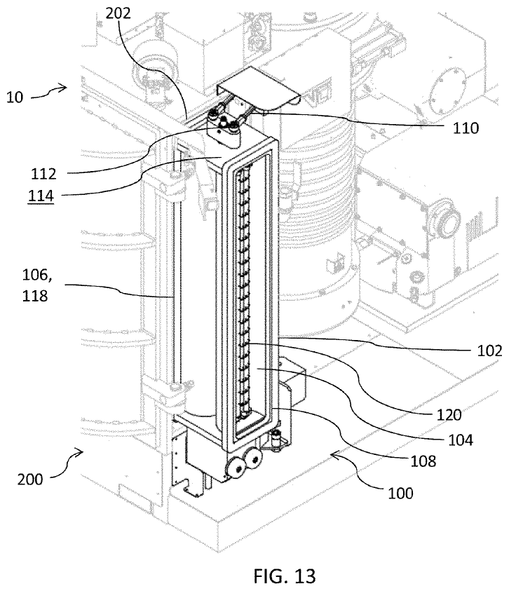

As shown in FIG. 12, in the rotated, retracted position, the second side 118 of the housing 102 is exposed, but the second side 118 of the housing 102 is positioned between the sealing surface 202 of the chamber 200 and the first side 108 of the housing 102. Further, the second side 118 is substantially parallel to the first side 108. With the second side 118 of the housing 102 facing the sealing surface 202 of the chamber 200, the housing 102 is moved, via the swing arms 110, back into the chamber 200 such that the second side 118 (with the second deposition area 106) is vacuum sealed flush with the sealing surface 202 of the chamber 200, as shown in FIG. 13. In an embodiment, the second side 118 of the housing 102 comprises a seal (not shown) for mating with the chamber 200 to create a vacuum seal in the second evaporative configuration.

With the evaporation source mechanism 100 in the second evaporative configuration, as shown in FIG. 13, the chamber 200 can then utilize the source(s) 120 in the second deposition area 106 for the coating process while the exposed first deposition area 104 is loaded/reloaded with one or more sources 120. In an embodiment, the entire movement of the evaporation source mechanism 100 from the first evaporative configuration to the second evaporative configuration takes seconds.

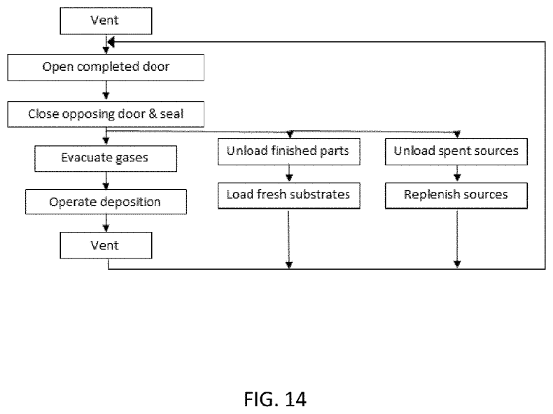

Referring now to FIG. 14, there is shown a flowchart of an operation sequence of the evaporation source mechanism 100, according to an embodiment. The operation sequence shown in FIG. 14, when executed by the evaporation system 10 shown in FIGS. 4-13, allows for the first side 108 of the housing 102 to be utilized in the coating process occurring within the chamber 200 while the second side 118 of the housing 102 is utilized in the loading/reloading process, and vice versa. For example, in the first evaporative configuration shown in FIG. 9, the first side 108 of the housing 102 with the first deposition area 104 is in the coating process under vacuum, while the second side 118 of the housing 102 with the second deposition area 106 is being prepared (i.e., loaded/reloaded) with one or more sources 120 (having evaporation materials, e.g., metals) for the next cycle (i.e., next coating process). This allows the maximum amount of space for operators to perform separate tasks (coating and loading/reloading) simultaneously.

Thereafter, when the coating cycle is complete, the evaporation source mechanism 100 rotates from the first evaporative configuration (FIG. 9) to the second evaporative configuration (FIG. 13) so that the source(s) 120 loaded/reloaded on the second deposition area 106 may be used in the next coating cycle, while the first deposition area 104 is loaded/reloaded with one or more sources 120. Note, some sources 120 are single-use sources that must be replaced after each coating cycle and some sources 120 are multi-use sources that can be recharged after each coating cycle. Therefore, the terms “loading” and “reloading” may be used interchangeably and include both the physical replacement of a source 120 and the recharging of a source 120.

In addition, the loading/reloading of sources 120 at the housing 102 not only occurs during the coating cycle, but also after each coating cycle. Generally, at the completion of each coating cycle in the chamber 200, a first user can remove coated substrates 210 from the chamber 200 and add new uncoated substrates 210 into the chamber 200 while a second user continues (or starts) loading/reloading sources 120 at the housing 102. In an embodiment of the chamber 200 with two doors 208, 209 (i.e., a double-door coating system 10), the removal/addition of substrates 210, coating process, and loading/reloading of sources 120 can all occur simultaneously, as shown in the flowchart in FIG. 14. For example, a first user loads uncoated substrates 210 into a first door 209, while a second user is loading/reloading the second deposition area 106 of the housing 102. The first user closes the first door 209 to begin the coating process with sources 120 previously loaded in the first deposition area 104 of the housing 102.

While the coating cycle occurs, the first user adds uncoated substrates 210 to the open, second door 208. The second user may still be loading/reloading sources 120 into the second deposition area 106. At the end of the coating cycle, the first user opens the first door 209 (with the now coated substrates 210) and closes the second door 208 (with the uncoated substrates 210) while the second user rotates the housing 102 to the second evaporative configuration wherein the second side 118 of the housing 102 is vacuum sealed to the sealing surface 202 of the chamber 200. As the second coating cycle occurs, with the first door 209 open and the first side 108 of the housing 102 exposed, the first user can remove the now coated substrates 210 from the first door 209 while the second user loads/reloads sources 120 in the first deposition area 104.

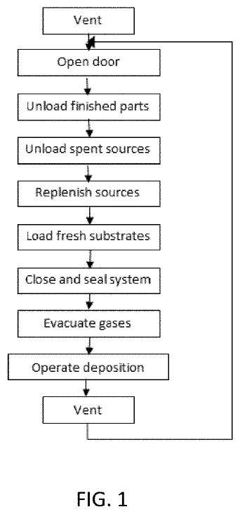

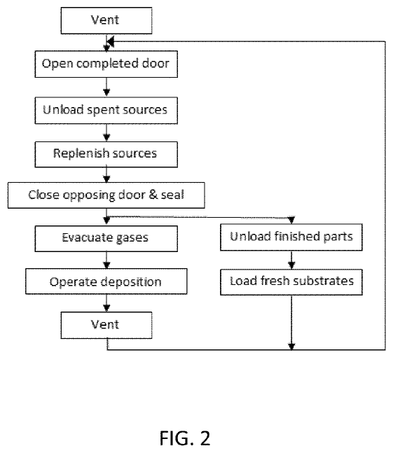

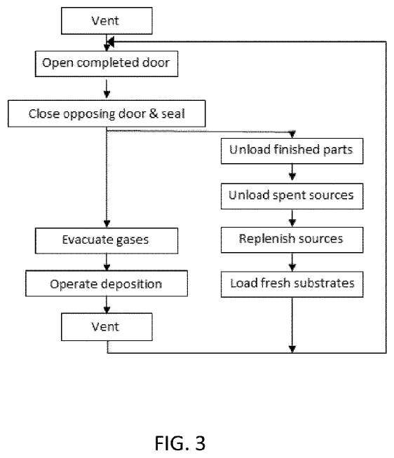

Therefore, the evaporation source mechanism 100 offers a more efficient method of operating an evaporative deposition coating system 10 than prior efforts as it permits separate tasks (coating, adding/removing substrates 210, and loading/reloading sources 120) to be performed by separate users at the same time, as described above, reducing the amount of time the system 10 needs to be prepared for the next coating cycle. Prior evaporation systems require the same space to be utilized for loading products and consumables. For example, prior systems require loading of both the substrates and sources within the chamber or into a door of the chamber. Thus, the sources can only be replaced/recharged after each coating cycle and the substrates can only be added/removed after each coating cycle, as shown in FIGS. 1-2, for example. In another example, as shown in FIG. 3, wherein the coating system is a double-door system, the sources are loaded/reloaded into the door and the substrates are added/removed to the door. In these systems, the sources are either between the door and structures holding the substrates or the sources are aligned down the center of structures holding the substrates. Therefore, in these prior systems, the location of the sources interferes with the addition/removal of the substrates.

The system 100 described herein permits the tasks (coating, adding/removing substrates 210, and loading/reloading sources 120) to be physically separate from one another, allowing for dedicated space to perform each task simultaneously. This permits more users to be effectively operating the equipment at one time, reducing the preparation time for the next system cycle. In order to achieve simultaneous execution of the tasks (coating, adding/removing substrates 210, and loading/reloading sources 120), the sources 120 in each of the deposition areas 104, 106 are electrically isolated from each other, permitting safe operation while the coating system 10 is in use.

In a particular embodiment, sources 120 in the first deposition area 104 are used to coat substrates 210 in a first door 209 during a first coating cycle. Simultaneously, the second deposition area 106 that is facing away from the chamber 200 (i.e., exposed) is loaded with one or more sources 120 having evaporation materials (e.g., copper, nickel, etc.) and prepared for the next coating cycle. In addition, uncoated substrates 210 are loaded into an open second door 208 of the chamber 200. After the first coating cycle, the chamber 200 is vented to the atmosphere and then the housing 102 is swung away from the chamber 200 and subsequently rotated approximately 180 degrees by the spring-loaded rotational bearings 112 while the first door 209 is opened and the now coated substrates 210 are removed. The second deposition area 106 is then returned to the port 204 on the chamber 200 and the second door 208 with the uncoated substrates 210 is closed, at which time the next cycle can commence. One or more sources 120 can be loaded/reloaded on the first side 108 of the housing 102 (in the first deposition area 104) that is now facing away from the chamber 200 (i.e., exposed) and the coated substrates 210 are removed from the first door 209 and replaced with uncoated substrates 210. This process repeats upon the end of each cycle, every time the chamber 200 is vented to the atmosphere, and simultaneously with the source loading/reloading and substrates addition/removal at different locations around the chamber 200. In an embodiment, the housing 102 may be made to function with an automated means instead of manual motion by an operator.

While various embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, embodiments may be practiced otherwise than as specifically described and claimed. Embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as, “has” and “having”), “include” (and any form of include, such as “includes” and “including”), and “contain” (any form of contain, such as “contains” and “containing”) are open-ended linking verbs. As a result, a method or device that “comprises”, “has”, “includes” or “contains” one or more steps or elements. Likewise, a step of method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts and equivalents of all means or step plus function elements in the claims below, if any, are intended to include any structure, material or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the present invention for various embodiments with various modifications as are suited to the particular use contemplated.

What is claimed is:

1. An evaporation source mechanism, comprising:
a housing having a first side and a second side;
wherein the housing is rotatable between a first evaporative configuration and a second evaporative configuration;
a first deposition area on the first side of the housing configured to temporarily store a first set of one or more sources;
a second deposition area on the second side of the housing configured to temporarily store a second set of one or more sources;
wherein in the first evaporative configuration, the first deposition area is configured for energizing the first set and the second deposition area is configured for loading the second set into the second deposition area; and
wherein in the second evaporative configuration, the second deposition area is configured for energizing the second set and the first deposition area is configured for loading the first set into the first deposition area.

2. The mechanism of claim 1, further comprising a rotation mechanism attached to a surface of the housing such that the housing is rotatable about the rotation mechanism.

3. The mechanism of claim 2, wherein the rotation mechanism comprises a stationary portion having pair of arms extending therefrom to the surface of the housing;

4. The mechanism of claim 3, further comprising one or more rotational bearings on the surface of the housing.

5. The mechanism of claim 4, wherein the pair of arms connect the stationary portion to the rotational bearings on the surface of the housing.

6. The mechanism of claim 1, wherein the first set and second set of one or more sources each include at least one of: a filament source, a crucible source, a boat source, and a box source.

7. The mechanism of claim 1, wherein the first set and second set of one or more sources includes an evaporation material composed of metal.

8. A coating system, comprising:
a vacuum chamber having a sealing surface;
an evaporation source mechanism, comprising:
a housing having a first side and a second side;
a first deposition area on the first side of the housing; and
a second deposition area on the second side of the housing;
wherein the housing of the evaporative source mechanism is rotatable between a first evaporative configuration and a second evaporative configuration relative to the sealing surface of the vacuum chamber; and
wherein in the first evaporative configuration, the first side of the housing is mated with the sealing surface of the vacuum chamber and in the second evaporative configuration, the second side of the housing is mated with the sealing surface of the vacuum chamber.

9. The system of claim 8, further comprising a port on the sealing surface of the vacuum chamber, wherein in the first evaporative configuration, the first deposition area is attached to the port and in the second evaporative configuration, and the second deposition area is attached to the port.

10. The system of claim 9, wherein in the first evaporative configuration, the port on the vacuum chamber receives an evaporation material from one or more sources in the first deposition area.

11. The system of claim 9, wherein in the first evaporative configuration, the second deposition area is configured to receive one or more sources comprising an evaporation material.

12. The system of claim 8, further comprising one or more electrical contacts on the sealing surface of the vacuum chamber, wherein the one or more electrical contacts are configured to provide power to the evaporative source mechanism when the housing is in the first and second evaporative configurations.

13. The system of claim 8, further comprising a rotation mechanism extending from the vacuum chamber to a surface of the housing such that the housing is rotatable about the rotation mechanism relative to the vacuum chamber.

14. The system of claim 13, wherein the rotation mechanism comprises a pair of arms extending from the vacuum chamber to the surface of the housing.

15. The system of claim 14, further comprising one or more rotational bearings on the surface of the housing, wherein the pair of arms connect the vacuum chamber to the rotational bearings on the surface of the housing.

16. A method for rapid cycle coating, comprising the steps of:
providing an evaporation system including a vacuum chamber having a sealing surface with a port, and an evaporation source mechanism comprising a housing having a first side and a second side, a first deposition area on the first side of the housing having a first set of one or more sources loaded therein, and a second deposition area on the second side of the housing, wherein the evaporation source mechanism is movably attached to the vacuum chamber;
sealing the first side of the housing to the sealing surface of vacuum chamber such that the port engages the first deposition area and the second side of the housing is exposed;
loading a second set of one or more sources into the second deposition area on the second side of the housing while evaporating an evaporation material from the first set of one or more sources loaded in the first deposition area;
rotating the housing and sealing the second side of the housing to the sealing surface of the vacuum chamber such that the port engages the second deposition area and the first side of the housing is exposed; and
evaporating an evaporation material from the second set of one or more sources loaded in the second deposition area via the port on the vacuum chamber while reloading the first set of one or more sources in the first deposition area on the exposed first side of the housing.

17. The method of claim 16, wherein the evaporation source mechanism is rotatably attached to the vacuum chamber by a rotation mechanism extending from the vacuum chamber to a surface of the housing.

18. The method of claim 17, wherein the rotation mechanism comprises a pair of arms extending from the vacuum chamber to rotatable bearings on the surface of the housing.

19. The method of claim 16, wherein the first set and second set of one or more sources each include at least one of: a filament source, a crucible source, a boat source, and a box source.

20. The method of claim 16, wherein the evaporation material from the first set and the evaporation material from the second set is composed of metal.
